(19) United States
(12) Patent Application Publication
(10) Pub. No.: US 2025/0225965 A1
(43) Pub. Date: Jul. 10, 2025

(54) USB Power Delivery Compatible Power Supply System

(71) Applicant: D’Addario & Company, Inc., Farmingdale, NY (US)

(72) Inventor: James D'Addario, Huntington, NY (US)

(21) Appl. No.: 18/989,353

(22) Filed: Dec. 20, 2024

Related U.S. Application Data
(60) Provisional application No. 63/618,068, filed on Jan. 5, 2024.

(51) Int. Cl. G10H 1/34; H03H 7/01

(52) U.S. Cl. CPC G10H 1/348; H03H 7/0115; H03H 7/0138; G10H 2230/035

(57) ABSTRACT

A power delivery and filter module for low frequency inductive filtering and a musical effects pedal assembly. The module has a USB PD-enabled input socket and a power output socket with an LC circuit therebetween. The LC circuit attenuates signals above a predetermined frequency to reduce undesired noise. The assembly includes one or more musical effects pedals with the power delivery and filter module electrically connected between the effects pedal and the power supply. Use of the module reduces or eliminates unwanted noise caused by switching technology in the USB power supply. The module may filter signals having a frequency of approximately 270 Hz and above.

### CROSS-REFERENCE TO RELATED APPLICATION

This application claims priority to U.S. Provisional Application No. 63/618,068 for USB Power Delivery Compatible Power Supply System, filed Jan. 5, 2024, the entire content of which is incorporated by reference.

### BACKGROUND

The disclosed embodiments relate to power delivery systems in the musical arts, and, in particular, to a USB Power Delivery (PD) gateway for power delivery for primary use with instrument effects pedals that significantly reduces or eliminates background noise associated with switching technology in USB and traditional non-USB power supplies.

In the musical arts, musicians often use effects pedals for altering the sounds and characteristics of their amplified musical instruments, such as guitars, mandolins, banjos, bass guitars, bowed family instruments, wind instruments, and any instrument equipped with an electronic pickup, sensor or microphone. It is common for such musicians to have numerous different pedals for creating different distortion effects. Oftentimes numerous pedals are kept together on a pedalboard that assists a player in managing multiple pedals by containing them mounted and attached for use, moving, packing and transporting without disassembly.

Each pedal must be electrically connected to a power supply for operation. Historically, pedals have been connected via an AC to DC power adaptor either directly, in series or in a daisy chain configuration. More recently, power supply modules and converters have been introduced for specific use with effects pedals. These products may include a rechargeable battery or may simply convert incoming voltage from a power source (AC or DC) to a preferred output voltage. Additionally, some products isolate current to multiple outputs and/or provide safety features such as automatic shutoff under certain conditions. With recent arrival and widespread adoption of alternative charging and power delivery protocols, such as USB, and in particular, USB PD protocol, modules or similar intermediary devices have been introduced that convert and pass power from a USB input to usable voltages for effects pedals.

USB PD carries several beneficial properties relative to older technology, including increased power delivery capabilities relative to earlier USB specifications, and power negotiation capabilities, whereby connected PD-compatible devices communicate to determine a preferred voltage level (i.e., “handshaking”). The capabilities of USB PD technology ultimately provide products with improved versatility, efficiency and safety.

In theory, any USB device with PD compatibility could be used to power effects pedals. Such power supplies often incorporate switching technology to efficiently convert input voltage (AC or DC) to the desired output voltage required by the device being powered (the load). Specific requirements for powering pedalboards are typically more demanding than requirements for charging other electronic products, such as mobile devices, for example. Incorporation of switching circuitry offers several advantages that contribute to the overall performance, safety, efficiency and compatibility of the power supply. However, the switching circuitry required for operating USB power supplies, whether batteries or AC adaptors, can impart noise artifacts within the audible frequency range (approximately 20-20,000 Hz). When operated to power instrument effects pedals, or any audio device using a USB power source, this results in unwanted background noise, such as humming, whining, pulsing or other artifacts that are unacceptable for this application. The background noise can be undesired or annoying, at best, and in some cases, can be so loud and disturbing that a pedal is unusable.

Filtering solutions or circuits for traditional, non-USB power supplies have recently been developed in an attempt to remove some of the audible noise caused by power supplies. Most such modules are configured for use with AC or DC power supplies; not for USB power supplies, which often generate the most unwanted noise due to the required switching technology. Additionally, all known commercially available filter module products filter only relatively high audio frequencies, which actually does not address considerable noise within the audible range described above.

It would thus be useful to provide a power delivery system for use with USB protocols, including those with USB PD-capability, that reduces or eliminates unwanted background noise, and which provides safe, clean and efficient power when used to power instrument effects pedals.

### SUMMARY

In one embodiment, a musical effects pedal assembly generally includes a USB PD-compatible power supply, at least one musical effects pedal electrically connected to the power supply and a power delivery and filter module connected between the power supply and the at least one musical effects pedal. The filter module has a USB PD-enabled input socket, a power output socket, and an LC circuit between the input socket and the output socket. The filter module negotiates power from the power supply at a predetermined voltage. The LC circuit attenuates signals above a predetermined frequency.

In another embodiment, a power delivery and filter module for low frequency inductive filtering has a USB PD-enabled input socket, a power output socket, and an LC circuit. The power output socket is downstream of the USB PD-enabled input socket with the LC circuit between them. The LC circuit attenuates signals above a predetermined frequency.

In yet another embodiment, a musical effects pedal assembly comprises a USB PD-compatible power supply with at least one musical effects pedal electrically connected to the power supply. A power delivery and filter module is connected between the power supply and the at least one musical effects pedal. The filter module includes a USB PD-enabled input socket and one or more power output sockets with an LC circuit between the input socket and the one or more output sockets. The filter module negotiates power from the power supply at a predetermined voltage and the LC circuit attenuates signals having a frequency of approximately 270 Hz and above.

### BRIEF DESCRIPTION OF THE DRAWINGS

FIG. 1 is a spectrum plot of the output of a USB-C PD power supply with a 20 mA load;

FIG. 2 is a spectrum plot of the output of the disclosed filter module attached to the USB-C PD power supply used in FIG. 1 with a 20 mA load;

FIG. 3 is a spectrum plot of a known product described as having supply side filtering attached to the USB-C PD power supply with a 20 mA load;

FIG. 4 is a spectrum plot of the output of a USB-C PD power supply with a 500 mA load;

FIG. 5 is a spectrum plot of the output of the disclosed filter module attached to the USB-C PD power supply with a 500 mA load;

FIG. 6 is a spectrum plot of the known product described as having supply side filtering attached to the USB-C PD power supply with a 500 mA load;

FIG. 7 is a spectrum plot showing the output of an exemplary guitar pedal chain powered by the USB-C PD power supply used in the FIGS. 1-6 plots;

FIG. 8 is a spectrum plot showing the output of the guitar pedal chain used in the example of FIG. 7 powered by the USB-C PD power supply with the disclosed filter module connected between the power supply and first pedal;

FIG. 9 is a spectrum plot showing the output of the guitar pedal chain used in the examples of FIGS. 7 and 8 powered by the USB-C PD power supply with the known product described as having supply side filtering connected between the power supply and first pedal;

FIG. 10 is a perspective view of an embodiment of the disclosed filter module having a USB-C PD input and a single output socket;

FIG. 11 is an elevation view of the PD filter module of FIG. 10 showing the input and output sockets;

FIG. 12 shows an exemplary circuit employed within a preferred embodiment of the filter module of FIGS. 10-11;

FIG. 13 is a photograph of the interior of an exemplary filter module in accordance with the disclosure;

FIG. 14A is a schematic diagram of the pedal chain used to generate the spectrum plot of FIG. 7;

FIG. 14B is a schematic diagram of the pedal chain used to generate the spectrum plots of FIGS. 8 and 9; and

FIG. 15 show multiple representative effects pedals connected in a chain for use with the disclosed filter module.

### DETAILED DESCRIPTION

Among the benefits and improvements disclosed herein, other objects and advantages of the disclosed embodiments will become apparent from the following wherein like numerals represent like parts throughout the figures. Detailed embodiments of PD filter module and related system, are disclosed; however, it is to be understood that the disclosed embodiments are merely illustrative of the invention that may be embodied in various forms. In addition, each of the examples given in connection with the various embodiments of the invention are intended to be illustrative, and not restrictive.

Throughout the specification and claims, the following terms take the meanings explicitly associated herein, unless the context clearly dictates otherwise. The phrase “in some embodiments” as used herein does not necessarily refer to the same embodiment(s), although it may. The phrases “in another embodiment” and “in some other embodiments” as used herein do not necessarily refer to a different embodiment, although it may. Thus, as described below, various embodiments may be readily combined without departing from the scope or spirit of the invention.

As used herein, “based on” is not exclusive and permits being based on additional factors not expressly described unless the applicable context clearly dictates otherwise.

In addition, as used herein, the term “or” is equivalent to the term “and/or,” unless the context clearly dictates otherwise. The term “based on” is not exclusive and allows for being based on additional factors not described unless the context clearly dictates otherwise. In addition, throughout the specification, the meaning of “a,” “an,” and “the” include plural references. The meaning of “in” includes “in” and “on.”

Further, the terms “substantial,” “substantially,” “similar,” “similarly,” “analogous,” “analogously,” “approximate,” “approximately,” and any combination thereof mean that differences between compared features or characteristics is less than 25% of the respective values/magnitudes in which the compared features or characteristics are measured and/or defined.

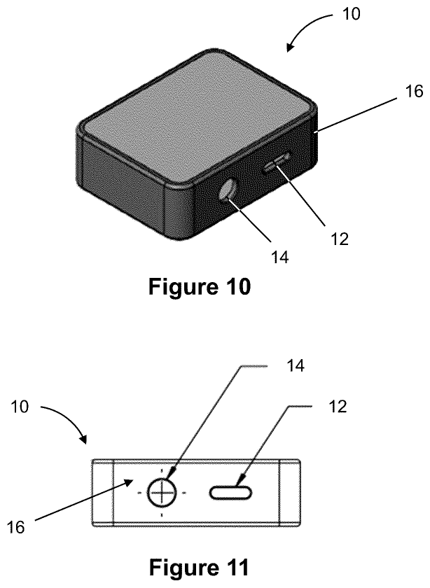

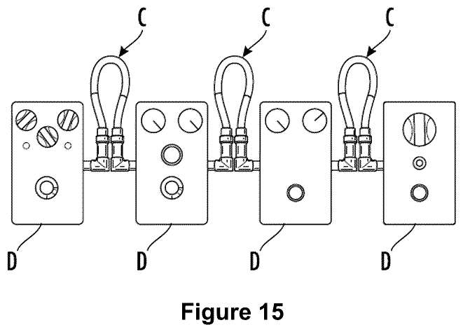

With reference first to FIGS. 10-13, disclosed herein is a PD filter module 10 with LC filter, an input socket 12 and an output socket 14. This embodiment includes a single output socket 14, however, the inventive concept is not limited as such. Embodiments exist with multiple output sockets for power delivery to multiple loads, whether instrument effects pedals (i.e., element D in FIG. 15) or other devices. In the depicted embodiment, the input socket 14 is a PD-enabled USB-C socket (3.0 or another protocol) which can receive power from any USB source, including AC or a power bank.

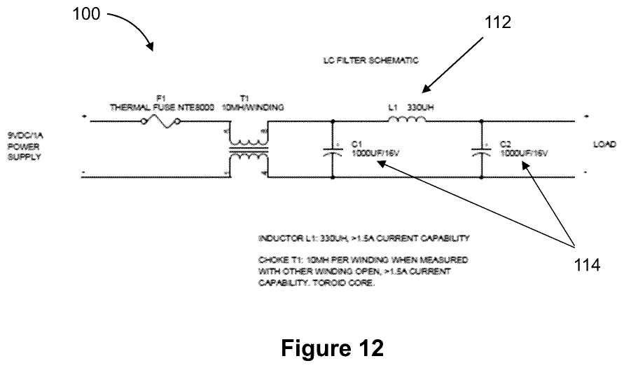

The noise filtration is provided via a two-stage inductive (112) and capacitive (114) filtering circuit configured to filter switching power supply noise that may come from USB power sources. The LC filter circuit included within the PD-enabled filter module 10 is tuned to remove the noise in the audible frequency from USB power sources. An exemplary circuit 100 for use within the disclosed filter module 10 is shown in FIG. 12. The depicted preferred embodiment of the filter module 10 is configured to deliver 9V power, since at present, the majority of instrument effects pedals are operable with 9V power. The delivery voltage of the preferred embodiment is non-limiting in that other embodiments exist for providing other voltages, such as 12V, 15V or 18V. Additionally, an embodiment exists that utilizes Programmable Power Supply (PPS) protocol that allows a connected device to request any voltage within a range of 5-20V, including fractional voltages.

In the depicted LC circuit of FIG. 12, the inductor 112 and capacitors 114 cooperate to create a resonance point, i.e., a cutoff frequency, at which point the impedance of the inductor and capacitor cancel each other out. This allows signals below a predetermined critical frequency to pass with minimal impedance, while attenuating (filtering out) signals above the predetermined frequency. The circuitry in the depicted preferred embodiment is programmed and tuned for use specifically with guitar effects pedals that are powered with 9V, however, this may be adjusted for other end uses. USB-C PD allows gateway circuits to request voltages from 3.6 to 20 VDC.

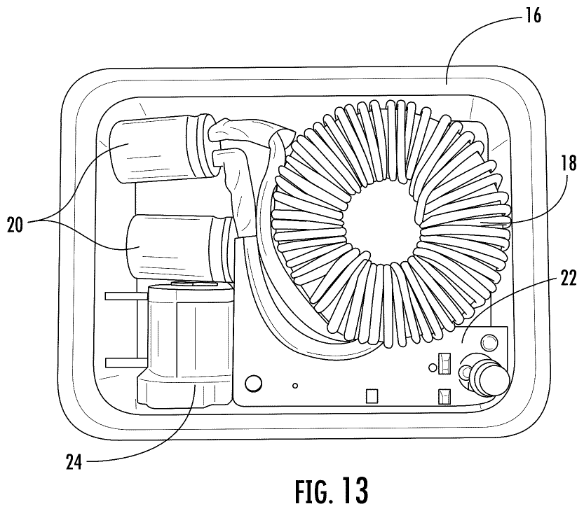

With reference to FIG. 13, the depicted preferred embodiment includes an LC filter circuit with a relatively large inductor 18 and two capacitors 20 electrically connected downstream from a USB-C connector 22 mounted on the bottom side of a printed circuit board and upstream of an output connector 24. In this embodiment, the filter module 10 includes 1000 uF capacitors 20 and a 330 uH inductor, which cooperate in the depicted circuit 100 to effectively filter lower frequencies than existing filter modules, approximately 270 Hz and above. This removes noise at the output end associated with an upstream USB power supply, including lower frequencies for which there was no solution previously. Other embodiments exist that are tuned to filter noise at even lower frequencies.

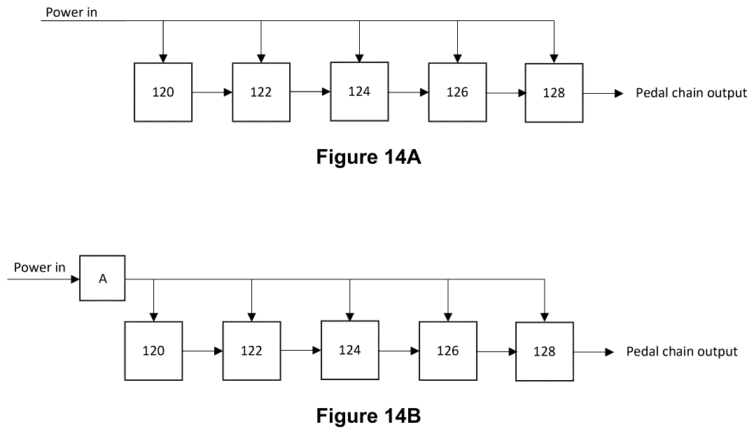

The efficacy of the disclosed filter module 10 can be appreciated with reference to comparative Examples 1-9, described below. With reference to FIGS. 14A and 14B, an identical chain setup of effects pedals was employed for each of Examples 7-9, including:
D′Addario & Company, Inc. guitar effect pedal tuner (120)
Keeley Compressor (122)
Crunch Box (124)
Boss Super Chorus CH-1 (126)
Keeley 30 ms Double Tracker (128)

With reference to FIG. 14B specifically, in Examples 8 and 9, a different power delivery module was placed at position A between the power source and the first pedal in the chain 120. Example 8 employed the inventive PD-enabled filter module 10 like that described with reference to FIGS. 10-13, and Example 9 employed a commercially available converter by Mission Engineering, Inc. with a USB-C input and which purports to provide filtering on the switching side and low noise performance compared to other products as the “Control Module”.

### EXAMPLES

### Example 1

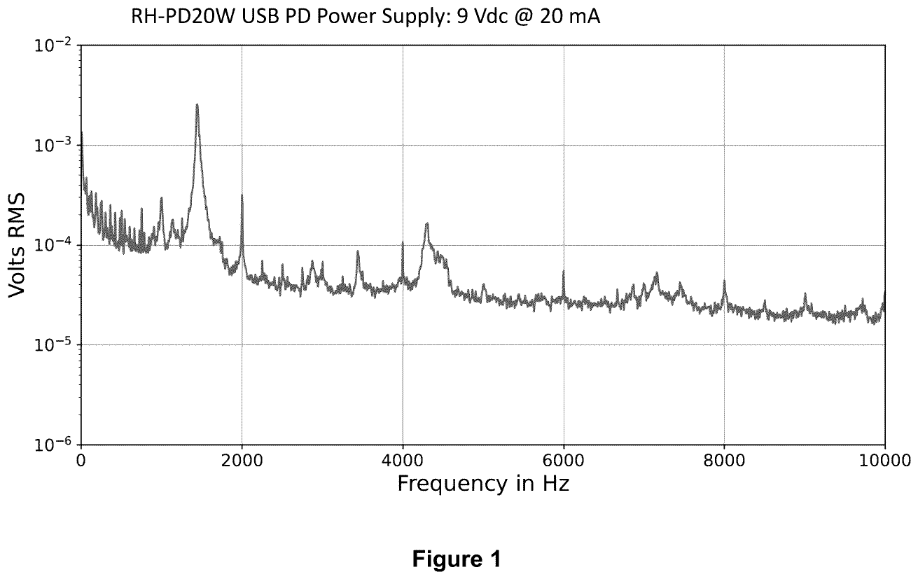

FIG. 1 is a plot of a noise spectrum at the output of the power supply with a 20 mA load and without a filter module (FIG. 14A). There is a substantial noise peak measuring about 3 mVrms at 1500 Hz in addition to smaller noise peaks throughout.

### Example 2

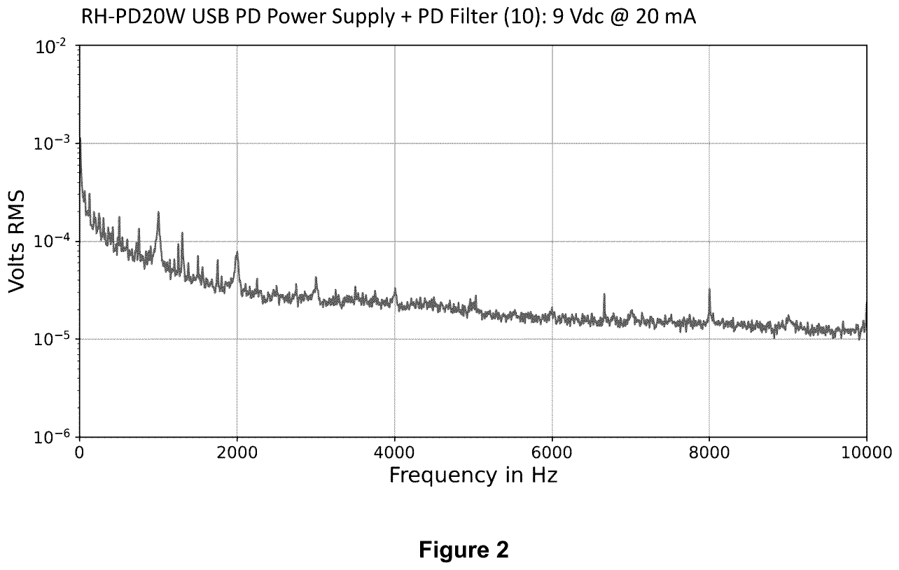

FIG. 2 is a plot of a noise spectrum at the output of the disclosed filter module 10 connected to the power supply with a 20 mA load. All noise peaks have been attenuated, including the large peak at 1500 Hz which is attenuated to below 0.1 mVrms (reduced by at least 30 dB).

### Example 3

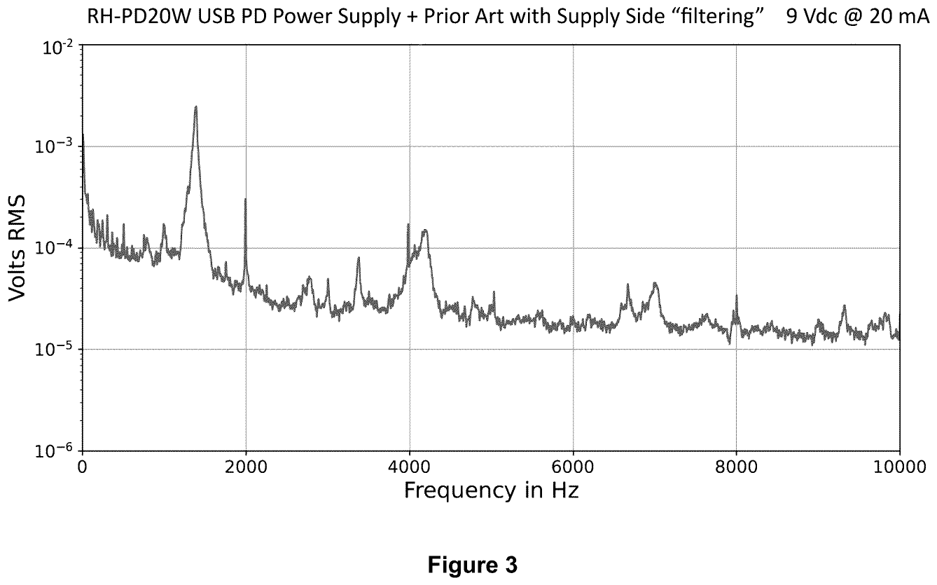

FIG. 3 is a plot of a noise spectrum at the output of the commercially available Control Module described above connected to the power supply with a 20 mA load. The spectrum is markedly similar to the power supply without any filtering.

### Example 4

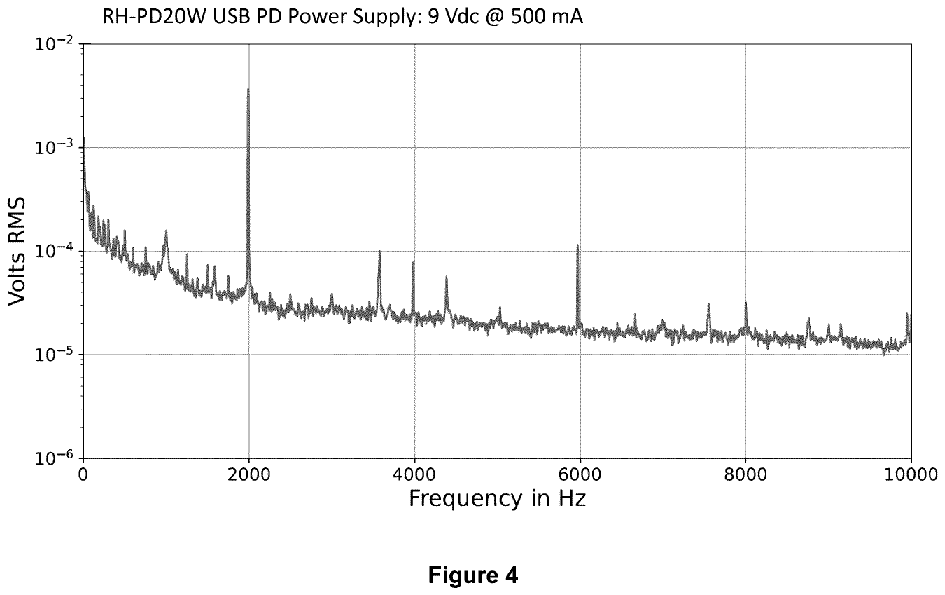

FIG. 4 is a plot of the same setup as Example 1, but with a 500 mA load. The large noise peak is present and has shifted to 2000 Hz.

### Example 5

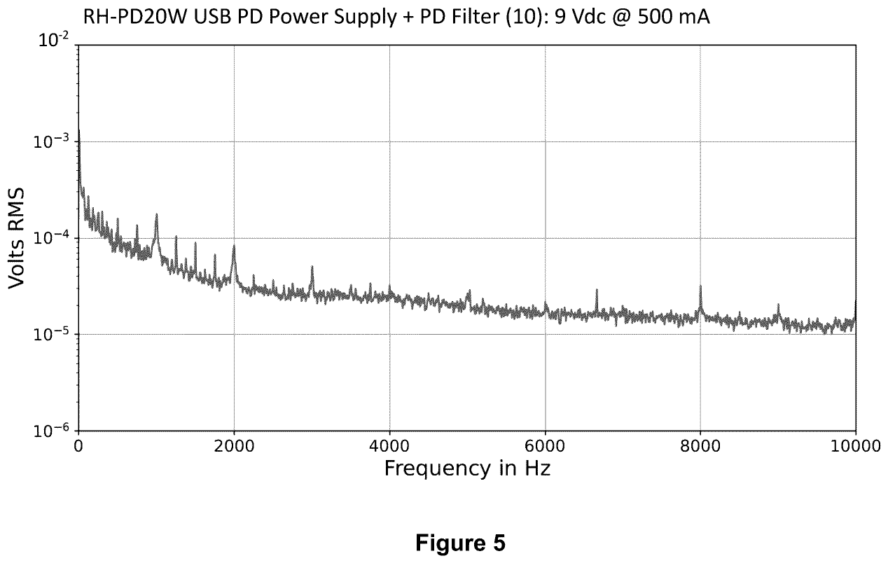

FIG. 5 is a plot of the same setup as FIG. 2, but with a 500 mA load. Like in Example 2, all noise peaks have been attenuated by the disclosed filter module 10, including the large peak at 2000 Hz.

### Example 6

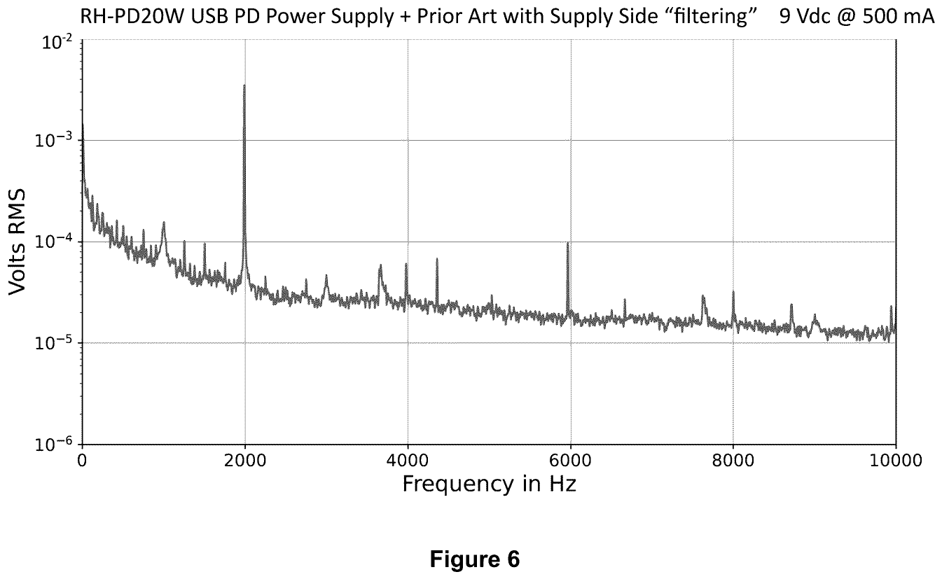

FIG. 6 is a plot of the same setup as Example 3, but with a 500 mA load. Again, the plot of the setup with the Control Module is similar in appearance to that of the setup without filter (FIG. 4).

### Example 7

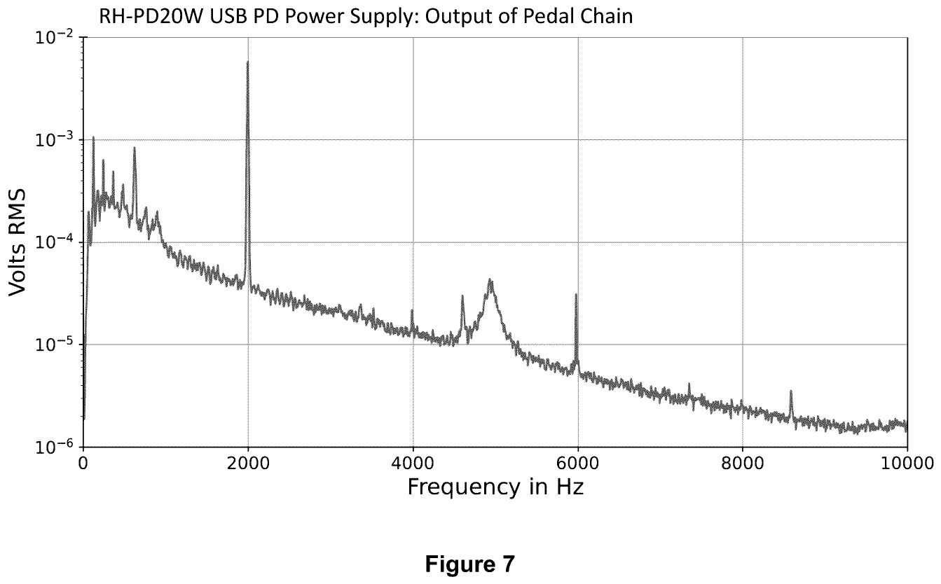

FIG. 7 shows a spectrum plot at the output of the pedal chain depicted in FIG. 14A and powered by the power supply used in the previous examples. Among many noise spikes, there is a significant noise spike of about 6 mVrms at 2000 Hz, which comes from the power supply. The noise at this frequency is audible.

### Example 8

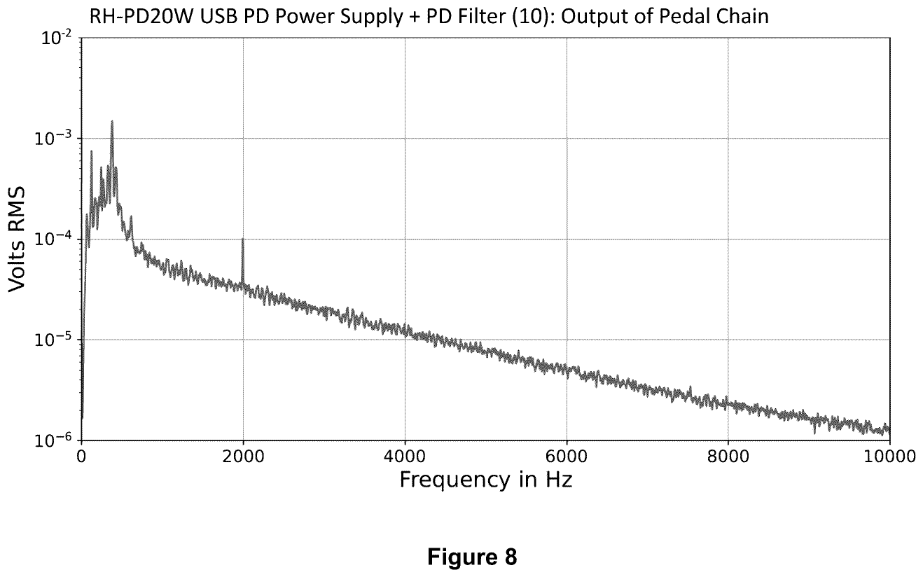

FIG. 8 shows a spectrum plot at the output of the pedal chain depicted in FIG. 14B with the inventive filter module 10 at location A and powered by the power supply used in the previous examples. The plot shows that the large 2000 Hz noise spike has been reduced to approximately 0.1 mVrms (by approximately 34 dB). The noise is no longer audible at this level. The other noise spikes have also been reduced.

### Example 9

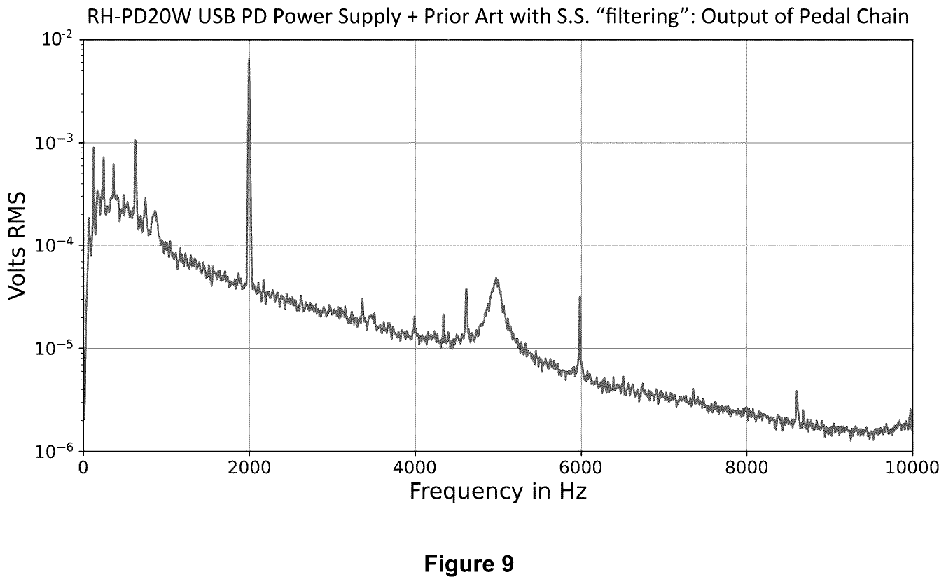

Finally, FIG. 9 shows a spectrum plot at the output of the pedal chain depicted in FIG. 14B with the Control Module at location A and powered by the power supply of the previous examples. Again, the spectrum is similar to that of FIG. 7 (the pedal chain with no filtering). Like in Example 7, the noise shown in this spectrum is audible.

In some embodiments, the filter module 10 includes circuitry for user and equipment safety, including switches or other circuitry that turns off power automatically if polarity is reversed at the output or input; output is shorted; a 9V power source is accidentally plugged into the output jack; and/or if 1.5 A current is exceeded.

While the depicted preferred embodiments of the filter module include a USB-C connection, this is a non-limiting characteristic, as other embodiments may exist that utilize a USB-A or USB-B connection. Further, the invention is not limited to a particular data speed protocol, i.e., USB 1.1, USB 2.0, USB 3.0, USB 4.0.

While a preferred embodiment has been set forth for purposes of illustration, the foregoing description should not be deemed a limitation of the invention herein. Accordingly, various modifications, adaptations and alternatives may occur to one skilled in the art without departing from the spirit of the invention and scope of the claimed coverage.

What is claimed is:

1. A musical effects pedal assembly, comprising:
a USB PD-compatible power supply;
at least one musical effects pedal electrically connected to the power supply; and
a power delivery and filter module connected between the power supply and the at least one musical effects pedal, wherein
the filter module comprises a USB PD-enabled input socket, a power output socket, and an LC circuit between the input socket and the output socket,
the filter module negotiates power from the power supply at a predetermined voltage, and
the LC circuit attenuates signals above a predetermined frequency.

2. The musical effects pedal assembly of claim 1, wherein the filter module is configured to negotiate 9V from a USB PD-compatible device connected to the USB PD-enabled socket and thereby deliver 9V of power at the output.

3. The musical effects pedal assembly of claim 2, wherein the input is a USB-C type socket.

4. The musical effects pedal assembly of claim 1, wherein the input is a USB-C type socket.

5. The musical effects pedal assembly of claim 4, wherein the LC circuit is configured to attenuate signals having a frequency of approximately 270 Hz and above.

6. The power delivery and filter module of claim 5, comprising a plurality of isolated output sockets, wherein each output socket is configured to deliver an adjustable output voltage, and wherein the output voltages may differ between each output socket.

7. The power delivery and filter module of claim 5, comprising a plurality of isolated output sockets, wherein each output socket is configured to deliver the same voltage as one another.

8. The power delivery and filter module of claim 5, wherein the voltage delivered by the output socket is adjustable.

9. The musical effects pedal assembly of claim 1, wherein the USB PD-enabled input socket is compatible with USB 3.0 protocol or above.

10. The musical effects pedal assembly of claim 1, wherein the USB PD-enabled input socket is operable with PPS protocol.

11. The musical effects pedal assembly of claim 1, wherein the LC circuit is a two-stage inductive and capacitive filtering circuit.

12. The musical effects pedal assembly of claim 1, wherein the LC circuit is configured to attenuate signals having a frequency of approximately 270 Hz and above.

13. The musical effects pedal assembly of claim 1, wherein the at least one musical effects pedal electrically connected to the power supply is secured on a pedalboard.

14. A power delivery and filter module for low frequency inductive filtering, comprising:
a USB PD-enabled input socket;
a power output socket downstream of the USB PD-enabled input socket; and
an LC circuit between the PD-enabled input socket and the output for attenuating signals above a predetermined frequency.

15. The power delivery and filter module of claim 1, wherein the filter module is configured to negotiate 9V from a USB PD-compatible device connected to the USB PD-enabled socket and thereby deliver 9V of power at the output.

16. The power delivery and filter module of claim 1, wherein the input is a USB-C type socket.

17. The power delivery and filter module of claim 1, wherein the USB PD-enabled input socket is compatible with USB 3.0 protocol or above.

18. The power delivery and filter module of claim 1, wherein the LC circuit is two-stage inductive and capacitive filtering circuit.

19. The power delivery and filter module of claim 1, wherein the LC circuit is configured to attenuate signals having a frequency of approximately 270 Hz and above.

20. A musical effects pedal assembly, comprising:
a USB PD-compatible power supply;
at least one musical effects pedal electrically connected to the power supply; and
a power delivery and filter module connected between the power supply and the at least one musical effects pedal, the filter module having a USB PD-enabled input socket, one or more power output sockets, and an LC circuit between the input socket and the one or more output sockets, wherein
the filter module negotiates power from the power supply at a predetermined voltage,
the LC circuit attenuates signals having a frequency of approximately 270 Hz and above.
